(19) United States
(12) Patent Application Publication
(10) Pub. No.: US 2024/0321803 A1
(43) Pub. Date: Sep. 26, 2024

(54) PHOTOSENSITIVE RESIN COMPOSITION, CURED FILM, AND SEMICONDUCTOR DEVICE

(71) Applicant: SUMITOMO BAKELITE CO., LTD., Shinagawa-ku, Tokyo (JP)

(72) Inventors: Akihiko Otoguro, Tokyo (JP); Keita Imai, Tokyo (JP); Yuki Ueda, Tokyo (JP); Toshiharu Kuboyama, Tokyo (JP)

(21) Appl. No.: 18/274,479

(22) PCT Filed: Feb. 10, 2022
(86) PCT No.: PCT/JP2022/005338

§ 371 Date: Jul. 27, 2023

(30) Foreign Application Priority Data
Feb. 15, 2021 (JP) 2021-021545
Jun. 25, 2021 (JP) 2021-105687

(51) Int. Cl. H01L 23/00; G03F 7/028; G03F 7/037; G03F 7/075

(52) U.S. Cl. CPC H01L 24/20; G03F 7/028; G03F 7/037; G03F 7/0752; H01L 2224/2101; H01L 2224/215; H01L 2924/37001

(57) ABSTRACT

The photosensitive resin composition of the present invention includes a polymer A having a structural unit represented by General Formula (a) and a polymer B including a polyimide having a group b represented by General Formula (b).

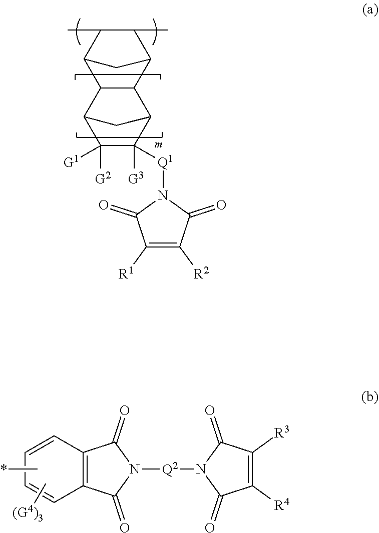

### TECHNICAL FIELD

The present invention relates to a photosensitive resin composition, a cured film, and a semiconductor device.

### BACKGROUND ART

Polyimide resins have been widely used as a protective material or an insulating material in liquid crystal display devices or semiconductors, or as a thin film for an electronic material of color filters and the like since the resins have high mechanical strength, heat resistance, insulating properties, and solvent resistance.

Patent Document 1 discloses a photosensitive composition including a polyimide with a predetermined maleimide group on a terminal.

Patent Document 2 discloses an optical waveguide having a core part including a first compound having a functional group that can be dimerized by light irradiation, and examples of the first compound include a cyclic olefin resin provided with a predetermined maleimide group as the functional group that can be dimerized, at a terminal.

### RELATED DOCUMENT

### Patent Document

[Patent Document 1] International Publication No. WO2020/181021
[Patent Document 2] Japanese Laid-open patent publication No. 2019-028115

### SUMMARY OF THE INVENTION

### Technical Problem

However, in the techniques in the related art described in Patent Documents 1 and 2, there was room for improvement in the dielectric loss tangent and the mechanical strength of a cured film obtained from the photosensitive resin composition.

### Solution to Problem

The present inventors have found that the problems can be solved by using a combination of a polyimide provided with a specific structure and a cyclic olefin resin, thus completing the present invention.

That is, the present invention can be shown below.

According to the present invention,
it is possible to provide a photosensitive resin composition including:
a polymer A having a structural unit represented by General Formula (a), and
a polymer B including a polyimide having a group b represented by General Formula (b).

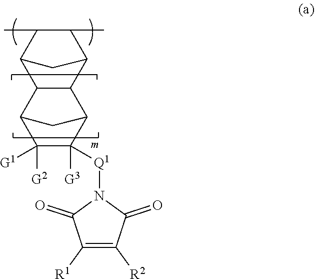

wherein, in General Formula (a), R¹ and R² each independently represent a hydrogen atom or an alkyl group having 1 to 3 carbon atoms, Q¹ represents a single bond or a divalent organic group, and G¹, G², and G³ each independently represent a hydrogen atom or a substituted or unsubstituted hydrocarbon group having 1 to 30 carbon atoms, and m is 0, 1, or 2,

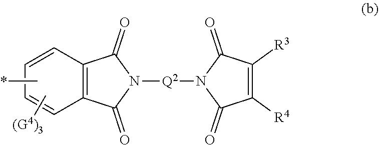

wherein, in General Formula (b), R³ and R⁴ each independently represent a hydrogen atom or an alkyl group having 1 to 3 carbon atoms, Q² represents a divalent organic group, and G⁴'s each independently represent a hydrogen atom or a substituted or unsubstituted hydrocarbon group having 1 to 30 carbon atoms, and * represents a bonding hand.

According to the present invention,
it is possible to provide a cured film including a cured product of the photosensitive resin composition.

According to the present invention,
it is possible to provide a semiconductor device provided with a resin film comprising the cured product of the photosensitive resin composition.

### Advantageous Effects of Invention

The photosensitive resin composition of the present invention makes it possible to obtain a cured product such as a film having a low dielectric loss tangent as well as excellent mechanical properties.

### BRIEF DESCRIPTION OF THE DRAWINGS

FIG. 1 is a schematic cross-sectional view of a semiconductor device according to the present embodiment.

### DESCRIPTION OF EMBODIMENTS

Hereinafter, embodiments of the present invention will be described with reference to drawings. Further, in all drawings, same components are designated by the same reference numerals, and description thereof will not be repeated as appropriate. In addition, for example, “1 to 10” represents “1 or more” through “10 or less” unless otherwise specified.

The photosensitive resin composition of the present embodiment includes the polymer A and the polymer B.

With this, the photosensitive resin composition of the present embodiment makes it possible to obtain a cured product such as a film, having an excellent low dielectric loss tangent and excellent mechanical properties.

Each component will be described below.

### [Polymer A]

The polymer A has a structural unit (a) represented by General Formula (a).

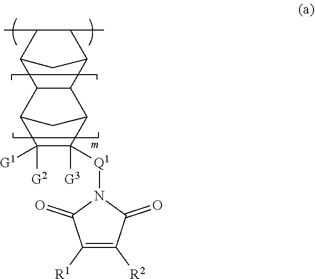

In General Formula (a), R¹ and R² each independently represent a hydrogen atom or an alkyl group having 1 to 3 carbon atoms. It is preferable that at least one of R¹ and R² is an alkyl group having 1 to 3 carbon atoms, and it is more preferable that the both of R¹ and R² are alkyl groups having 1 to 3 carbon atoms. From the viewpoint of the effects of the present invention, the alkyl group having 1 to 3 carbon atoms is preferably an alkyl group having 1 or 2 carbon atoms, and more preferably an alkyl group having 1 carbon atom.

Q¹ represents a single bond or a divalent organic group.

As the divalent organic group, a known organic group can be used within a range where the effects of the present invention are exhibited, and examples thereof include an alkylene group having 1 to 8 carbon atoms or a (poly)alkylene glycol chain. The alkylene group having 1 to 8 carbon atoms is preferably an alkylene group having 2 to 6 carbon atoms.

Examples of the alkylene group having 1 to 8 carbon atoms include a methylene group, an ethylene group, a propylene group, a butylene group, a pentylene group, a hexylene group, a heptylene group, and an octylene group.

The alkylene oxide constituting the (poly)alkylene glycol chain is not particularly limited, but the (poly)alkylene glycol chain is preferably composed of an alkylene oxide having 1 to 18 carbon atoms, more preferably an alkylene oxide having 2 to 8 carbon atoms, such as ethylene oxide, propylene oxide, butylene oxide, isobutylene oxide, 1-butene oxide, 2-butene oxide, trimethylethylene oxide, tetramethylene oxide, tetramethylethylene oxide, butadiene monoxide, and octylene oxide.

G¹, G², and G³ each independently represent a hydrogen atom or a substituted or unsubstituted hydrocarbon group having 1 to 30 carbon atoms.

Examples of the hydrocarbon group having 1 to 30 carbon atoms include an alkyl group, an alkenyl group, an alkynyl group, an alkylidene group, an aryl group, an aralkyl group, an alkaryl group, and cycloalkyl group.

Examples of the alkyl group include a methyl group, an ethyl group, an n-propyl group, an isopropyl group, an n-butyl group, an isobutyl group, a sec-butyl group, a tert-butyl group, pentyl group, a neopentyl group, a hexyl group, a heptyl group, an octyl group, a nonyl group, and a decyl group.

Examples of the alkenyl group include an allyl group, a pentenyl group, and a vinyl group. Examples of the alkynyl group include an ethynyl group.

Examples of the alkylidene group include a methylidene group and an ethylidene group.

Examples of the aryl group include a phenyl group, a naphthyl group, and an anthracenyl group. Examples of the aralkyl groups include a benzyl group and a phenethyl group.

Examples of the alkaryl group include a tolyl group and a xylyl group. Examples of the cycloalkyl group include an adamantyl group, a cyclopentyl group, a cyclohexyl group, and a cyclooctyl group.

The hydrocarbon group having 1 to 30 carbon atoms may include at least one atom selected from O, N, S, P, and Si in the structure.

In the present embodiment, the hydrocarbon group having 1 to 30 carbon atoms is preferably a hydrocarbon group having 1 to 15 carbon atoms, and more preferably a hydrocarbon group having 1 to 10 carbon atoms. The hydrocarbon group having 1 to 30 carbon atoms is preferably an alkyl group having 1 to 30 carbon atoms, more preferably an alkyl group having 1 to 15 carbon atoms, and still more preferably an alkyl group having 1 to 10 carbon atoms.

Examples of the substituent of the substituted hydrocarbon group having 1 to 30 carbon atoms include a hydroxyl group, an amino group, a cyano group, an ester group, an ether group, an amide group, and a sulfonamide group, and the hydrocarbon group may be substituted with at least one of those groups.

In the present embodiment, it is preferable that any one of G¹, G², and G³ is a substituted or unsubstituted hydrocarbon group having 1 to 30 carbon atoms and the rest are hydrogen atoms, and it is more preferable that all of G¹, G², and G³ are hydrogen atoms.

m is 0, 1, or 2, preferably 0 or 1, and more preferably 0.

The polymer A of the present embodiment is excellent in a low dielectric loss tangent since it is provided with the structure represented by General Formula (a). Furthermore, since the polymer A has a predetermined maleimide group in a side chain thereof and can be photodimerized without causing a radical reaction, a photopolymerization between the polymers A or between the polymer A and a polyimide included in a polymer B which will be described later can be performed, resulting in a more excellent mechanical strength.

The polymer A of the present embodiment can be synthesized as follows.

First, a compound (a′) represented by General Formula (a′) is addition-polymerized, and as necessary, further addition-polymerized with another norbornene-based compound, to obtain a polymer. The addition polymerization is performed, for example, by coordination polymerization.

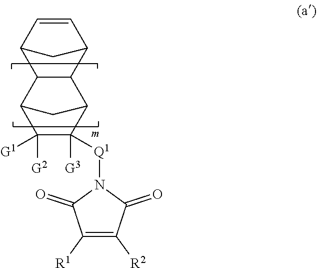

In General Formula (a′), R¹, R², Q¹, G¹, G², G³, and m each have the same definitions as in General Formula (a).

Examples of such another norbornene-based compound include norbornenes having an alkyl group, such as 5-methylnorbornene, 5-ethylnorbornene, 5-butylnorbornene, 5-hexylnorbornene, 5-decylnorbornene, 5-cyclohexylnorbornene, and 5-cyclopentylnorbornene, norbornenes having an alkenyl group, such as 5-ethylidenenorbornene, 5-vinylnorbornene, 5-propenylnorbornene, 5-cyclohexenylnorbornene, and 5-cyclopentenylnorbornene, and norbornenes having an aromatic ring, such as 5-phenylnorbornene, 5-phenylmethylnorbornene, 5-phenylethylnorbornene, and 5-phenylpropylnorbornene.

In the present embodiment, solution polymerization can be performed by dissolving the compound and an organometallic catalyst in a solvent, and then heating the solution for a predetermined period of time. At this time, the heating temperature can be, for example, 30° C. to 200° C., preferably 40° C. to 150° C., and more preferably 50° C. to 120° C. In the present embodiment, the yield of the polymer (A) can be improved by making the heating temperature higher than a heating temperature in the related art.

In addition, the heating time can be, for example, 0.5 hours to 72 hours. Furthermore, it is more preferable that the solution polymerization is performed after removing dissolved oxygen in the solvent by nitrogen bubbling.

In addition, a molecular weight modifier and a chain transfer agent can be used, as necessary. Examples of the chain transfer agent include alkylsilane compounds such as trimethylsilane, triethylsilane, and tributylsilane. These chain transfer agents may be used alone or in combination of two or more kinds thereof.

As the solvent used in the polymerization reaction, for example, one kind or two or more kinds of alcohols such as methyl ethyl ketone (MEK), propylene glycol monomethyl ether, diethyl ether, tetrahydrofuran (THF), toluene, ethyl acetate, and butyl acetate, and esters such as methyl alcohol, ethyl alcohol, and isopropyl alcohol can be used.

The organometallic catalyst is not particularly selected as long as it makes addition polymerization proceed but, for example, a phosphine-based or diimine-based ligand, and the like may be coordinated with a palladium complex and a nickel complex, and a counter anion and the like may be used. One kind or two or more kinds of these can be used.

Examples of the palladium complex include allylpalladium complexes such as (acetato-κ0)(acetonitrile)bis[tris(1-methylethyl)phosphine]palladium (I) tetrakis(2,3,4,5,6-pentafluorophenyl)borate, and a π-allylpalladium chloride dimer,
organic carboxylates of palladium, such as palladium acetate, palladium propionate, palladium maleate, and palladium naphthoate,
complexes of an organic carboxylic acid of palladium, such as a palladium acetate-triphenylphosphine complex, a palladium acetate-tri(m-tolyl)phosphine complex, and palladium acetate-tricyclohexylphosphine complex,
organic sulfonates of palladium, such as palladium dibutyl phosphite and p-toluenesulfonate,
β-diketone compounds of palladium, such as bis(acetylacetonate) palladium, bis(hexafluoroacetylacetonate) palladium, bis(ethylacetoacetate) palladium, and bis(phenylacetoacetate) palladium, and
complexes of halides of palladium, such as dichlorobis(triphenylphosphine)palladium, bis[tri(m-tolylphosphine)]palladium, dibromobis[tri(m-tolylphosphine)]palladium, and acetonyltriphenylphosphonium complexes.

Examples of the phosphine ligand include triphenylphosphine, dicyclohexylphenylphosphine, cyclohexyldiphenylphosphine, and tricyclohexylphosphine.

Examples of the counter anion include triphenylcarbeniumtetrakis(pentafluorophenyl)borate, triphenylcarbeniumtetrakis[3,5-bis(trifluoromethyl)phenyl]borate, triphenylcarbeniumtetrakis(2,4,6-trifluorophenyl)borate, triphenylcarbenium tetraphenylborate, tributylammonium tetrakis(pentafluorophenyl)borate, N,N-dimethylanilinium tetrakis(pentafluorophenyl)borate, N,N-diethylanilinium tetrakis(pentafluorophenyl)borate, N,N-diphenylanilinium tetrakis(pentafluorophenyl)borate, and lithium tetrakis(pentafluorophenyl)borate.

The amount of the organometallic catalyst can be set to be from 300 ppm to 5,000 ppm, preferably from 1,000 ppm to 3,500 ppm, and more preferably from 1,500 ppm to 2,500 ppm with respect to the norbornene-based monomer. With these ranges, the yield of the polymer A can be improved.

The polymer A is precipitated by adding the obtained reaction solution including the polymer A to an alcohol such as hexane and methanol. Then, the polymer A is collected by filtration, washed with an alcohol such as hexane and methanol, and dried.

In the present embodiment, for example, the polymer A can be synthesized in this manner.

According to the production method of the present embodiment, the polymer A can be obtained with a high yield of 70% or more.

The conversion with dialkyl maleic anhydride is preferably 30% or more. The conversion is more preferably 40% or more, and more preferably 50% or more. With these ranges, the polyimide component eluted by development can be reduced.

The polymer A of the present embodiment can include other structural units other than the structural unit (a) within a range where the effects of the present invention are exhibited, and examples of such other structural units include structural units derived from norbornene-based compounds other than those mentioned above.

In a case where the polymer B which will be described later does not include a halogen atom in the structure, specifically in a case where R⁵ and R⁶ in General Formula (b1) are each a hydrogen atom, an alkyl group having 1 to 3 carbon atoms, or a hydroxyl group, and X is a single bond, an alkylene group having 1 to 4 carbon atoms, a divalent ether group derived from bisphenol A, a divalent ether group derived from bisphenol F, or a divalent ether group derived from bisphenol S, the weight-average molecular weight of the polymer A can be set to 3,000 to 30,000, preferably 4,000 to 20,000, and more preferably 4,500 to 15,000, from the viewpoint of the compatibility between the polymer A and the polymer B.

On the other hand, in a case where the polymer B which will be described later includes a halogen atom in the structure, specifically in a case where any one of R⁵, R⁶, and X in General Formula (b1) is a halogen atom-containing group, the polymer B has excellent compatibility. Therefore, from the viewpoint of the compatibility between the polymer A and the polymer B, the weight-average molecular weight of the polymer A can be set to 3,000 to 300,000, preferably 4,000 to 250,000, and more preferably 4,500 to 200,000.

### [Polymer B]

The polymer B includes a polyimide having a group b represented by General Formula (b).

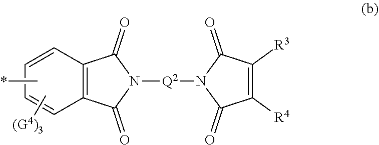

In General Formula (b), R³ and R⁴ each independently represent a hydrogen atom or an alkyl group having 1 to 3 carbon atoms. It is preferable that at least one of R³ and R⁴ is an alkyl group having 1 to 3 carbon atoms, and it is more preferable that the both of R³ and R⁴ are alkyl groups having 1 to 3 carbon atoms. From the viewpoint of the effects of the present invention, the alkyl group having 1 to 3 carbon atoms is preferably an alkyl group having 1 or 2 carbon atoms, and more preferably an alkyl group having 1 carbon atom. * represents a bonding hand.

G⁴'s each independently represent a hydrogen atom or a substituted or unsubstituted hydrocarbon group having 1 to 30 carbon atoms. The substituted or unsubstituted hydrocarbon group having 1 to 30 carbon atoms is the same as for G¹, G², and G³.

In the present embodiment, it is preferable that any one of a plurality of G⁴'s is preferably a substituted or unsubstituted hydrocarbon group having 1 to 30 carbon atoms and the rest are hydrogen atoms, and it is more preferable that all of G⁴'s are hydrogen atoms.

Q² represents a divalent organic group.

As the divalent organic group, a known organic group can be used as long as the effects of the present invention are exhibited, and examples thereof include an organic group represented by General Formula (b1).

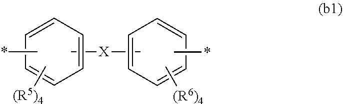

In General Formula (b1), R⁵ and R⁶ each independently represent a hydrogen atom, a haloalkyl group having 1 to 4 carbon atoms, an alkyl group having 1 to 3 carbon atoms, an alkoxy group having 1 to 3 carbon atoms, or a hydroxyl group. R⁵ and R⁶ are each preferably an alkyl group having 1 to 3 carbon atoms or a haloalkyl group having 1 to 4 carbon atoms, and more preferably an alkyl group having 1 or 2 carbon atoms or a haloalkyl group having 1 or 2 carbon atoms.

The haloalkyl group having 1 to 4 carbon atoms may be linear or branched, and examples thereof include a fluoromethyl group, a difluoromethyl group, a trifluoromethyl group, a 2-fluoroethyl group, a 1,1,2-trifluoroethyl group, a 1,1,2,2-tetrafluoroethyl group, a 2,2,2-trifluoroethyl group, a pentafluoroethyl group, 3-fluoropropyl group, a heptafluoropropyl group, a 1,1,2,3,3,3-hexafluoropropyl group, a 1,2,2,3,3,3-hexafluoropropyl group, a 4-fluorobutyl group, a nonafluorobutyl group; a chloromethyl group, a dichloromethyl group, a trichloromethyl group, a 2-chloroethyl group, a 1,1,2-trichloroethyl group, a 1,1,2,2-tetrachloroethyl group, a 2,2,2-trichloroethyl group, a pentachloroethyl group, a 3-chloropropyl group, a heptachloropropyl group, a hexachloropropyl group, a 1,2,2,3,3,3-hexachloropropyl group, a 4-chlorobutyl group, and a nonachlorobutyl group.

Examples of the alkyl group having 1 to 3 carbon atoms include a methyl group, an ethyl group, an n-propyl group, and an isopropyl group.

Examples of the alkoxy group having 1 to 3 carbon atoms include a methoxy group, an ethoxy group, an n-propoxy group, and an isopropoxy group.

X represents a single bond, an alkylene group having 1 to 4 carbon atoms, a haloalkylene group having 1 to 4 carbon atoms, a divalent ether group derived from bisphenol A, a divalent ether group derived from bisphenol F, a divalent ether group derived from bisphenol S, or a divalent ether group derived from hexafluorobisphenol A, and is preferably the single bond or the alkylene group having 1 to 4 carbon atoms, and more preferably the single bond or an alkylene group having 1 or 2 carbon atoms.

Examples of the alkylene group having 1 to 4 carbon atoms include a methylene group, an ethylene group, a trimethylene group, a propylene group, and a butylene group.

Examples of the haloalkylene group having 1 to 4 carbon atoms include a fluoromethylene group, a difluoromethylene group, a fluoroethylene group, a 1,2-difluoroethylene group, a trifluoroethylene group, a perfluoroethylene group, a perfluoropropylene group, a perfluorobutylene group, a chloromethylene group, a chloroethylene group, a chloropropylene group, a bromomethylene group, a bromoethylene group, a bromopropylene group, a methylene iodide group, an ethylene iodide group, and a propylene iodide group.

* represents a bonding hand.

From the viewpoint of the effects of the present invention, the polymer B preferably includes a polyimide provided with the group b represented by General Formula (b) at at least one terminal, and preferably both terminals.

Since the polymer B of the present embodiment is provided with the group b represented by General Formula (b), it has an excellent mechanical strength. Furthermore, since the polyimide has a predetermined maleimide group at a terminal thereof and can be photodimerized without causing a radical reaction, a photopolymerization between the polyimides included in polymer B or between the polymer A and the polyimide can be performed, resulting in a more excellent mechanical strength.

In addition, the polymer (B) may include a polyimide provided with a group c represented by General Formula (c) at at least one terminal.

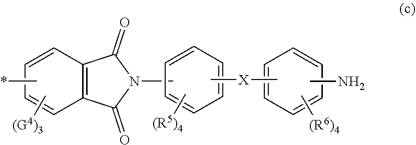

In General Formula (c), R⁵, R⁶, and X each have the same definitions as in General Formula (b1), and G⁴ has the same definition as in General Formula (b).

In a case where the polyimide included in the polymer (B) includes a polyimide provided with the group c, the ratio (b/b+c) of the number of moles of the group b to the total number of moles of the group b and the group c can be set to 0.50 or more, preferably 0.55 or more, and more preferably 0.60 or more. With these ranges, the polyimide component eluted by development can be reduced.

From the viewpoint of the effects of the present invention, the polymer B preferably includes a polyimide represented by General Formula (d).

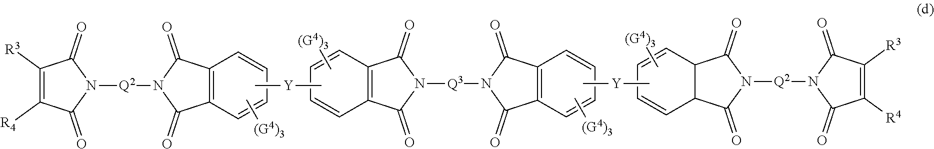

In General Formula (d), R³, R⁴, and Q² each have the same definitions as in General Formula (b), and a plurality of R³'s, a plurality of R⁴'s, a plurality of Q²'s, and a plurality of G⁴'s may each be the same as or different from each other.

Y is selected from groups represented by General Formula (d1), General Formula (d2), and General Formula (d3), and a haloalkylene group having 1 to 5 carbon atoms, and a plurality of Y's may be the same as or different from each other.

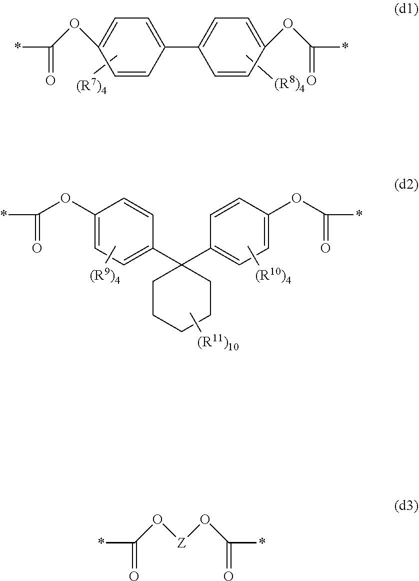

In General Formula (d1), R⁷ and R⁸ each independently represent a hydrogen atom, an alkyl group having 1 to 3 carbon atoms, or an alkoxy group having 1 to 3 carbon atoms, and a plurality of R⁷'s and a plurality of R⁸'s may each be the same as or different from each other. * represents a bonding hand.

From the viewpoint of the effects of the present invention, it is preferable that R⁷ and R⁸ are each the hydrogen atom or the alkyl group having 1 to 3 carbon atoms, and it is more preferable that at least one of R⁷'s and at least one of R⁸'s are each the alkyl group having 1 to 3 carbon atoms, it is still more preferable that three R⁷'s are alkyl groups having 1 to 3 carbon atoms, it is even still more preferable that one R⁷ is the hydrogen atom, three R⁸'s are the alkyl groups having 1 to 3 carbon atoms, and one R⁸ is the hydrogen atom, it is particularly preferable that three R⁷'s are methyl groups, one R⁷ is the hydrogen atom, three R⁸'s are methyl groups, and one R⁸ is the hydrogen atom.

* represents a bonding hand.

In General Formula (d2), R⁹ and R¹⁰ each independently represent a hydrogen atom, an alkyl group having 1 to 3 carbon atoms, or an alkoxy group having 1 to 3 carbon atoms, and a plurality of R⁹'s and a plurality of R¹⁰'s may each be the same as or different from each other.

From the viewpoint of the effects of the present invention, R⁹ and R¹º are preferably the hydrogen atom or the alkyl group having 1 to 3 carbon atoms, and more preferably the hydrogen atom.

R¹¹ represents a hydrogen atom, an alkyl group having 1 to 3 carbon atoms, or an alkoxy group having 1 to 3 carbon atoms, and a plurality of R¹¹'s may be the same as or different from each other.

From the viewpoint of the effects of the present invention, R¹¹ is preferably the hydrogen atom or the alkyl group having 1 to 3 carbon atoms, and more preferably the hydrogen atom.

* represents a bonding hand.

In General Formula (d3), Z represents an alkylene group having 1 to 5 carbon atoms or a divalent aromatic group.

Examples of the divalent aromatic group include a phenylene group, a divalent biphenyl group, and a naphthylene group.

* represents a bonding hand.

By allowing the polyimide of the present embodiment to include a compound (polymer) having groups represented by General Formula (d1), General Formula (d2), and General Formula (d3) in the main chain in Y, thus enabling the polymer main chain to withstand deformation and improving slippage between the polymer chains. As a result, it is possible to obtain a cured product such as a film, which has a remarkably improved elongation, an excellent mechanical strength, and excellent dimensional stability due to a suppressed curing shrinkage.

In General Formula (d), Q³ represents a repeating unit represented by General Formula (d4).

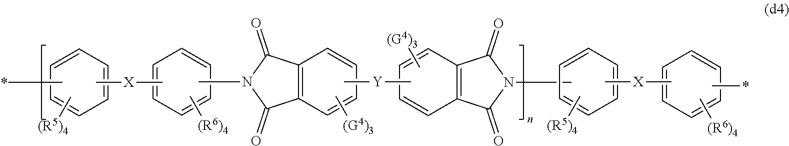

In General Formula (d4), R⁵, R⁶, and X each have the same definitions as in General Formula (b1), Y has the same definition as in General Formula (d), and G⁴ has the same definition as in General Formula (b).

n represents an integer of 20 to 200, and preferably an integer of 30 to 180.

* represents a bonding hand.

The weight-average molecular weight of the polyimide included in the polymer B of the present embodiment is 10,000 to 300,000, and preferably 15,000 to 200,000.

In addition, since the polyimide of the present embodiment has an excellent solubility in a solvent and does not need to be varnished in a precursor state, a varnish including the polymer B can be prepared and a cured product such as a film, having an excellent dimensional stability, can be obtained from the varnish.

### <Method for Producing Polyimide>

The polyimide of the present embodiment can be synthesized as follows.

A diamine (i) represented by General Formula (i), an acid anhydride (ii) represented by General Formula (ii), and a maleic anhydride derivative (iii) represented by General Formula (iii) are reacted.

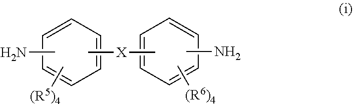

In General Formula (i), X, R⁵, and R⁶ each have the same definitions as in General Formula (b1).

As diamine (i), one or more compounds represented by General Formula (i) can be used.

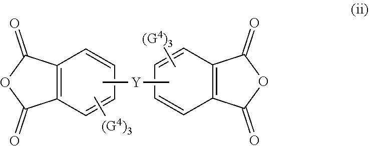

In General Formula (ii), G⁴ has the same definition as in General Formula (b) and Y has the same definition as in General Formula (d).

As the acid anhydride (ii), one or more compounds represented by General Formula (ii) can be used.

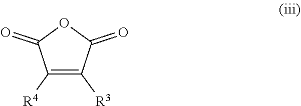

In General Formula (iii), R³ and R⁴ each have the same definitions as in General Formula (b).

As the maleic anhydride derivative (iii), one or more compounds represented by General Formula (iii) can be used.

The equivalence ratio of the diamine (i) and the acid anhydride (ii) in the reaction is an important factor that determines the molecular weight of a polyimide thus obtained. In general, it is well known that there is a correlation between the molecular weight and mechanical properties of a polymer, and the higher the molecular weight the better the mechanical properties. Therefore, in order to obtain a polyimide having a practically excellent strength, it is necessary to have a certain degree of a high molecular weight. In the present invention, the equivalence ratio of the diamine (i) and the acid anhydride (ii) to be used is not particularly limited, but the equivalence ratio of the acid anhydride (ii) to the diamine (i) is preferably in the range of 0.80 to 1.06. In a case where the equivalence ratio is less than 0.80, the molecular weight is low and brittleness is caused, resulting in a low mechanical strength. In addition, in a case where the equivalence ratio is more than 1.06, the unreacted carboxylic acid may be decarboxylated during heating to cause gas generation and foaming, which is thus not preferable.

The amount of the maleic anhydride derivative (iii) can be preferably set to 30% by mole to 100% by mole, more preferably set to 40% by mole to 100% by mole, and still more preferably set to 50% by mole to 100% by mole in the polynorbornene.

With these amounts, the photosensitivity by photodimerization can be imparted to the polyimide, and a cured product such as a film, having an excellent mechanical properties as well as an excellent low dielectric loss tangent, can be obtained.

The reaction can be performed by a known method in an organic solvent.

Examples of the organic solvent include aprotic polar solvents such as γ-butyrolactone (GBL), N,N-dimethylformamide, N,N-dimethylacetamide, tetrahydrofuran, diethylene glycol dimethyl ether, diethylene glycol diethyl ether, cyclohexanone, and 1,4-dioxane, and one kind or a combination of two or more kinds of the organic solvents may be used. At this time, a nonpolar solvent compatible with the aprotic polar solvent may be mixed and used. Examples of the nonpolar solvent include aromatic hydrocarbons such as toluene, ethylbenzene, xylene, mesitylene, and solvent naphtha. Any of proportions of the nonpolar solvent in the mixed solvent can be set according to the resin properties and the states such as a stirring device capacity and a solution viscosity as long as the solubility of the solvent decreases and the polyamic acid resin obtained by the reaction does not precipitate.

The reaction is performed at a reaction temperature equal to or higher than 0° C. and equal to or lower than 100° C., and preferably equal to or higher than 20° C. and equal to or lower than 80° C. for about 30 minutes to 2 hours, and then performed at a reaction temperature equal to or higher than 100° C. and equal to or lower than 250° C., and preferably equal to or higher than 120° C. and equal to or lower than 200° C. for about 1 to 5 hours.

The maleic anhydride derivative (iii) may be present in an imidization reaction of the diamine (i) with the acid anhydride (ii), but during the reaction or after completion of the reaction of the diamine (i) with the acid anhydride (ii), the maleic anhydride derivative (iii) dissolved in the organic solvent can be added and reacted to block a polyimide terminal.

In a case where the maleic anhydride derivative (iii) is separately added, the reaction is preferably performed at a temperature that is equal to or higher than 100° C. and equal to or lower than 250° C., and preferably equal to or higher than 120° C. and equal to or lower than 200° C. for about 1 to 5 hours after the addition.

Through the steps above, a reaction solution including the polyimide (terminal-blocked polyimide) of the present embodiment can be obtained, and as necessary, the reaction solution can be diluted with an organic solvent and the like and used as a polymer solution (coating varnish). As the organic solvent, those exemplified in the reaction step can be used, and the organic solvent may be the same one as in the reaction step or may be a different organic solvent.

In addition, the reaction solution may be put into a poor solvent to reprecipitate the polyimide, thereby removing unreacted monomers, followed by drying and solidifying. Then, the resultant is dissolved again in an organic solvent, and can thus be used as a purified product. In particular, in applications where impurities and foreign matters are problematic, it is preferable to dissolve the resultant in an organic solvent again to obtain a filtration-purified varnish.

The polyimide concentration in the polymer solution (100% by weight) is not particularly limited, but is about 10% to 30% by weight.

In the present embodiment, from the viewpoint of the effects of the present invention, the ratio of the polymer A to the polymer B (A:B) can be set to 5:95 to 95:5, preferably 10:90 to 90:10, more preferably 20:80 to 80:20, still more preferably 30:70 to 70:30, and particularly preferably 40:60 to 60:40.

From the viewpoints of a tensile strength and an elongation, the molecular weight of the polymer B can be set to 30,000 to 200,000, preferably 40,000 to 180,000, and more preferably 50,000 to 150,000.

### [Photosensitizer]

The photosensitive resin composition of the present embodiment can further include a photosensitizer.

Examples of the photosensitizer include benzophenone-based photopolymerization initiators, thioxanthone-based photopolymerization initiators, benzyl-based photopolymerization initiators, and Michler's ketone-based photopolymerization initiators. Among these, the benzophenone-based photopolymerization initiators and the thioxanthone-based photopolymerization initiators are preferable.

Examples of the benzophenone-based photopolymerization initiators include benzophenone, 4-chlorobenzophenone, 4,4′-dimethoxybenzophenone, 4,4′-diaminobenzophenone, 4-phenylbenzophenone, isophthalphenone, and 4-benzoyl-4′-methyl-diphenyl sulfide. These benzophenones and derivatives thereof can improve a curing speed by using a tertiary amine as a hydrogen donor.

Examples of commercially available benzophenone-based photopolymerization initiators include SPEEDCURE MBP (4-methylbenzophenone), SPEEDCURE MBB (methyl-2-benzoylbenzoate), SPEEDCURE BMS (4-benzoyl-4′-methyl diphenyl sulfide), SPPEDCURE PBZ (4-phenyl benzophenone), and SPPEDCURE EMK (4,4′-bis(diethylamino)benzophenone) (all trade names, manufactured by DKSH Japan K. K.).

Examples of the thioxanthone-based photopolymerization initiators include thioxanthone, diethylthioxanthone, isopropylthioxanthone, and chlorothioxanthone. As the diethylthioxanthone, 2,4-diethylthioxanthone is preferable, as the isopropylthioxanthone, 2-isopropylthioxanthone is preferable, and as the chlorothioxanthone, 2-chlorothioxanthone is preferable. Among those, the thioxanthone-based photopolymerization initiators including diethylthioxanthone are more preferable.

Examples of commercially available thioxanthone-based photopolymerization initiators include Speedcure DETX (2,4-diethylthioxanthone), Speedcure ITX (2-isopropylthioxanthone), Speedcure CTX (2-chlorothioxanthone), and SPEEDCURE CPTX (1-chloro-4-propylthioxanthone) (all trade names, manufactured by DKSH Japan K. K.), and KAYACURE DETX (2,4-diethylthioxanthone) (trade name, manufactured by Nippon Kayaku Co., Ltd.).

The addition amount of the photosensitizer is not particularly limited, but is preferably about 0.05% to 10% by mass, more preferably about 0.1% to 7.5% by mass, and still more preferably about 0.2% to 5% by mass of the total solid content of the photosensitive resin composition. By setting the addition amount of the photosensitizer within the range, the patterning property of the photosensitive resin layer including the photosensitive resin composition can be enhanced, and the long-term storage stability of the photosensitive resin composition can be improved.

### [Adhesion Aid]

The photosensitive resin composition of the present embodiment can further include an adhesion aid.

With this, the adhesiveness of a resin film or a pattern formed of the photosensitive resin composition to a substrate can be enhanced.

A usable adhesion aid is not particularly limited. For example, silane coupling agents such as aminosilane, epoxysilane, acrylsilane, mercaptosilane, vinylsilane, ureidosilane, acid anhydride-functional silane, and sulfidesilane can be used. The silane coupling agents may be used alone or in combination of two or more kinds thereof. Among these, the epoxysilane (that is, a compound including, in one molecule, both an epoxy moiety and a group that generates a silanol group by hydrolysis) or the acid anhydride-functional silane (that is, a compound including, in one molecule, an acid anhydride group and a group that generates a silanol group by hydrolysis) are preferable. The group opposite to the silane of the silane coupling agent can further enhance the adhesiveness to a substrate of a resin film or a pattern formed of the photosensitive resin composition through the bonding to the polymer A or the polymer B, the improvement of intimacy with the polymer, and the like.

Examples of the aminosilane include bis(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-β(aminoethyl) γ-aminopropyltrimethoxysilane, N-β(aminoethyl) γ-aminopropyltriethoxysilane, N-β(aminoethyl) γ-aminopropylmethyldimethoxysilane, N-β(aminoethyl) γ-aminopropylmethyldiethoxysilane, and N-phenyl-γ-amino-propyltrimethoxysilane.

Examples of the epoxysilane include γ-glycidoxypropyltrimethoxysilane, γ-glycidoxypropylmethyldiethoxysilane, β-(3,4-epoxycyclohexyl)ethyltrimethoxysilane, and γ-glycidylpropyltrimethoxysilane.

Examples of the acrylic silane include γ-(methacryloxypropyl)trimethoxysilane, γ-(methacryloxypropyl)methyldimethoxysilane, and γ-(methacryloxypropyl)methyldiethoxysilane.

Examples of the mercaptosilane include 3-mercaptopropyltrimethoxysilane.

Examples of the vinylsilane include vinyltris(3-methoxyethoxy)silane, vinyltriethoxysilane, and vinyltrimethoxysilane.

Examples of the ureidosilane include 3-ureidopropyltriethoxysilane.

Examples of the acid anhydride-functional silane include 3-trimethoxysilylpropylsuccinic anhydride.

Examples of the sulfide silane include bis(3-(triethoxysilyl)propyl)disulfide and bis(3-(triethoxysilyl)propyl)tetrasulfide.

In a case of using an adhesion aid, the adhesion aid may be used alone or in combination of two or more kinds thereof.

The content of the adhesion aid is usually 0.01 to 10 parts by mass, and preferably 0.05 to 5 parts by mass in a case where the total solid content of the photosensitive resin composition is assumed to be 100 parts by mass. It is considered that by setting the content of the adhesion aid within these ranges, it is possible to obtain a sufficient “adhesiveness” which is the effect of the adhesion aid while maintaining a balance with other performances.

### (Solvent)

The photosensitive resin composition according to the present embodiment can include a urea compound or an amide compound having an acyclic structure as a solvent. The solvent preferably includes, for example, a urea compound. With this, it is possible to further improve the adhesiveness between a cured product of the photosensitive resin composition and a metal such as Al and Cu.

Furthermore, in the present specification, the urea compound indicates a compound provided with a urea bond. In addition, the amide compound indicates a compound provided with an amide bond, that is, an amide. Moreover, specific examples of the amide include primary amides, secondary amides, and tertiary amides.

In addition, in the present embodiment, the acyclic structure means that the structure of a compound is not provided with a cyclic structure such as a carbocyclic ring, an inorganic ring, or a heterocyclic ring. Examples of the structure of a compound which is not provided with a cyclic structure include a straight-chain structure and a branched-chain structure.

As the urea compound and the amide compound having an acyclic structure, those having a large number of nitrogen atoms in the molecular structure are preferable. Specifically, it is preferable that the number of nitrogen atoms in the molecular structure is 2 or more. With this, it is possible to increase the number of lone electron pairs. Therefore, the adhesiveness to a metal such as Al and Cu can be improved.

Specific examples of the structure of the urea compound include a cyclic structure and an acyclic structure. Among the specific examples, the acyclic structure is preferable as the structure of the urea compound. With this, it is possible to improve the adhesiveness between a cured product of the photosensitive resin composition and a metal such as Al and Cu. A reason thereof is presumed to be as follows. It is presumed that a urea compound with an acyclic structure forms a coordinate bond more easily than a urea compound with a cyclic structure. This is considered to be caused by a configuration that the urea compound having an acyclic structure is less constrained in molecular motion and has a higher degree of freedom in deformation of the molecular structure than the urea compound having a cyclic structure. Therefore, in a case where the urea compound having an acyclic structure is used, a strong coordinate bond can be formed and the adhesiveness can be improved.

Specific examples of the urea compound include tetramethylurea (TMU), 1,3-dimethyl-2-imidazolidinone, N,N-dimethylacetamide, tetrabutylurea, N,N′-dimethylpropyleneurea, 1,3-dimethoxy-1,3-dimethylurea, N,N′-diisopropyl-O-methylisourea, O,N,N′-triisopropylisourea, O-tert-butyl-N,N′-diisopropylisourea, O-ethyl-N,N′-diisopropylisourea, and O-benzyl-N,N′-diisopropylisourea. As the urea compound, one kind or a combination of two or more kinds of the specific examples can be used. As the urea compound, among the specific examples, for example, one kind or two or more kinds selected from the group consisting of tetramethylurea (TMU), tetrabutylurea, 1,3-dimethoxy-1,3-dimethylurea, N,N′-diisopropyl-O-methylisourea, O,N,N′-triisopropylisourea, O-tert-butyl-N,N′-diisopropylisourea, O-ethyl-N,N′-diisopropylisourea, and O-benzyl-N,N′-diisopropylisourea is preferably used, and tetramethylurea (TMU) is more preferably used. With this, a strong coordinate bond can be formed and the adhesiveness can be improved.

Specific examples of the amide compound having an acyclic structure include 3-methoxy-N,N-dimethylpropanamide, N,N-dimethylformamide, N,N-dimethylpropionamide, N,N-diethylacetamide, 3-butoxy-N,N-dimethylpropanamide, and N,N-dibutylformamide.

The photosensitive resin composition according to the present embodiment may include, as a solvent, a solvent provided with no nitrogen atom in addition to the urea compound and the amide compound having an acyclic structure.

Specific examples of the solvents provided with no nitrogen atom include ether-based solvents, acetate-based solvents, alcohol-based solvents, ketone-based solvents, lactone-based solvents, carbonate-based solvents, sulfone-based solvents, ester-based solvents, and aromatic hydrocarbon-based solvents. As the solvent provided with no nitrogen atom, one kind or a combination of two or more kinds of the specific examples can be used.

Specific examples of the ether-based solvents include propylene glycol monomethyl ether (PGME), propylene glycol monoethyl ether, ethylene glycol monoethyl ether, diethylene glycol dimethyl ether, diethylene glycol monoethyl ether, diethylene glycol, ethylene glycol diethyl ether, diethylene glycol diethyl ether, diethylene glycol dibutyl ether, dipropylene glycol monomethyl ether, and 1,3-butylene glycol-3-monomethyl ether.

Specific examples of the acetate-based solvents include propylene glycol monomethyl ether acetate (PGMEA), methyl lactate, ethyl lactate, butyl lactate, and methyl-1,3-butylene glycol acetate.

Specific examples of the alcohol-based solvents include tetrahydrofurfuryl alcohol, benzyl alcohol, 2-ethylhexanol, butanediol, and isopropyl alcohol.

Specific examples of the ketone-based solvents include cyclopentanone, cyclohexanone, diacetone alcohol, and 2-heptanone.

Specific examples of the lactone-based solvents include γ-butyrolactone (GBL) and γ-valerolactone.

Specific examples of the carbonate-based solvents include ethylene carbonate and propylene carbonate.

Specific examples of the sulfone-based solvents include dimethylsulfoxide (DMSO) and sulfolane.

Specific examples of the ester-based solvents include methyl pyruvate, ethyl pyruvate, and methyl-3-methoxypropionate.

Specific examples of the aromatic hydrocarbon-based solvents include mesitylene, toluene, and xylene.

Among the solvents, more preferred solvents are PGMEA and cyclopentanone. By using these, the solubility of the polymer A (polynorbornene) and the polymer B (polyimide) can be improved.

The lower limit value of the content of the urea compound and the amide compound having an acyclic structure in the solvent is, for example, preferably 10 parts by mass or more, more preferably 20 parts by mass or more, still more preferably 30 parts by mass or more, even more preferably 50 parts by mass or more, and further more preferably 70 parts by mass or more in a case where the content of the solvent is assumed to be 100 parts by mass. With this, it is possible to further improve the adhesiveness between a cured product of the photosensitive resin composition and a metal such as Al and Cu.

The lower limit value of the content of the urea compound and the amide compound having an acyclic structure in the solvent can be, for example, 100 parts by mass or less in a case where the solvent is assumed to be 100 parts by mass. From the viewpoint of improving the adhesiveness, it is preferable that the content of the urea compound and the amide compound having an acyclic structure is high in the solvent.

### (Surfactant)

The photosensitive resin composition according to the present embodiment may further include a surfactant.

The surfactant is not limited, and specific examples thereof include nonionic surfactants, such as polyoxyethylene alkyl ethers such as polyoxyethylene lauryl ether, polyoxyethylene stearyl ether, and polyoxyethylene oleyl ether; polyoxyethylene aryl ethers such as polyoxyethylene octylphenyl ether and polyoxyethylene nonylphenyl ether; and polyoxyethylene dialkyl esters such as polyoxyethylene dilaurate and polyoxyethylene distearate; commercially available fluorine-based surfactants such as F-TOP EF301, F-TOP EF303, and F-TOP EF352 (manufactured by Shin-Akita Chemical Co., Ltd.), MEGAFACE F171, MEGAFACE F172, MEGAFACE F173, MEGAFACE F177, MEGAFACE F444, MEGAFACE F470, MEGAFACE F471, MEGAFACE F475, MEGAFACE F482, and MEGAFACE F477 (manufactured by DIC Corporation), FLUORAD FC-430, FLUORAD FC-431, NOVEC FC4430, and NOVEC FC4432 (manufactured by 3M Japan), and SURFLON S-381, SURFLON S-382, SURFLON S-383, SURFLON S-393, SURFLON SC-101, SURFLON SC-102, SURFLON SC-103, SURFLON SC-104, SURFLON SC-105, and SURFLON SC-106 (manufactured by AGC Seimi Chemical Co., Ltd.); Combined KP341 (manufactured by Shin-Etsu Chemical Co., Ltd.); and (meth)acrylic acid-based copolymer POLYFLOW Nos. 57 and 95 (manufactured by Kyoeisha Chemical Co., Ltd.).

Among those, the fluorine-based surfactant having a perfluoroalkyl group is preferably used. Among the specific examples of the fluorine-based surfactant having a perfluoroalkyl group, one kind or two or more kinds of MEGAFACE F171, MEGAFACE F173, MEGAFACE F444, MEGAFACE F470, MEGAFACE F471, MEGAFACE F475, MEGAFACE F482, and MEGAFACE F477 (manufactured by DIC Corporation), SURFLON S-381, SURFLON S-383, and SURFLON S-393 (manufactured by AGC Seimi Chemical Co., Ltd.), and NOVEC FC4430 and NOVEC FC4432 (manufactured by 3M Japan) are preferably used.

In addition, as the surfactant, a silicone-based surfactant (for example, polyether-modified dimethylsiloxane) can also be preferably used. Specific examples of the silicone-based surfactant include SH series, SD series, and ST series from Dow Corning Toray Co., Ltd., BYK series from BYK Chemie Japan K. K., KP series from Shin-Etsu Chemical Co., Ltd., DISFOAM (registered trademark) series from NOF Corporation, and TSF series from Toshiba Silicone Co., Ltd.

The upper limit value of the content of the surfactant in the photosensitive resin composition is preferably 1% by mass (10,000 ppm) or less, more preferably 0.5% by mass (5,000 ppm) or less, and still more preferably 0.1% by mass (1,000 ppm) or less with respect to the entire photosensitive resin composition (including a solvent).

In addition, the lower limit value of the content of the surfactant in the photosensitive resin composition is not particularly limited, but from the viewpoint of sufficiently obtaining the effect of the surfactant, the lower limit value is, for example, 0.001% by mass (10 ppm) or more with respect to the entire photosensitive resin composition (including a solvent).

By appropriately adjusting the amount of the surfactant, it is possible to improve the applicability and the uniformity of a coating film while maintaining other performances.

### (Antioxidant)

The photosensitive resin composition according to the present embodiment may further include an antioxidant. As the antioxidant, one or more selected from a phenol-based antioxidant, a phosphorus-based antioxidant, and a thioether-based antioxidant can be used. The antioxidant can suppress the oxidation of a resin film formed from the photosensitive resin composition.

Examples of the phenol-based antioxidant include pentaerythrityl-tetrakis[3-(3,5-di-t-butyl-4-hydroxyphenyl)propionate], 3,9-bis{2-[3-(3-t-butyl-4-hydroxy-5-methylphenyl)propionyloxy]-1,1-dimethylethyl}2,4,8,10-tetraoxaspiro[5,5]undecane, octadecyl-3-(3,5-di-t-butyl-4-hydroxyphenyl)propionate, 1,6-hexanediol-bis[3-(3,5-di-t-butyl-4-hydroxyphenyl)propionate], 1,3,5-trimethyl-2,4,6-tris(3,5-di-t-butyl-4-hydroxybenzyl)benzene, 2,6-di-t-butyl-4-methylphenol, 2,6-di-t-butyl-4-ethylphenol, 2,6-diphenyl-4-octadecyloxyphenol, stearyl(3,5-di-t-butyl-4-hydroxyphenyl)propionate, distearyl(3,5-di-t-butyl-4-hydroxybenzyl)phosphonate, thiodiethylene glycol bis[(3,5-di-t-butyl-4-hydroxyphenyl)propionate], 4,4′-thiobis(6-t-butyl-m-cresol), 2-octylthio-4,6-di(3,5-di-t-butyl-4-hydroxyphenoxy)-s-triazine, 2,2′-methylenebis(4-methyl-6-t-butyl-6-butylphenol), 2,2′-methylenebis(4-ethyl-6-t-butylphenol), bis[3,3-bis(4-hydroxy-3-t-butylphenyl)butyric acid]glycol ester, 4,4′-butylidenebis(6-t-butyl-m-cresol), 2,2′-ethylidenebis(4,6-di-t-butylphenol), 2,2′-ethylidenebis(4-s-butyl-6-t-butylphenol), 1,1,3-tris(2-methyl-4-hydroxy-5-t-butylphenyl)butane, bis[2-t-butyl-4-methyl-6-(2-hydroxy-3-t-butyl-5-methylbenzyl)phenyl]terephthalate, 1,3,5-tris(2,6-dimethyl-3-hydroxy-4-t-butylbenzyl)isocyanurate, 1,3,5-tris(3,5-di-t-butyl-4-hydroxybenzyl)-2,4,6-trimethylbenzene, 1,3,5-tris[(3,5-di-t-butyl-4-hydroxyphenyl)propionyloxyethyl]isocyanurate, tetrakis[methylene-3-(3,5-di-t-butyl-4-hydroxyphenyl)propionate]methane, 2-t-butyl-4-methyl-6-(2-acryloyloxy-3-t-butyl-5-methylbenzyl)phenol, 3,9-bis(1,1-dimethyl-2-hydroxyethyl)-2,4-8,10-tetraoxaspiro[5,5]undecane-bis[β-(3-t-butyl-4-hydroxy-5-methylphenyl)propionate], triethylene glycol-bis[β-(3-t-butyl-4-hydroxy-5-methylphenyl)propionate], 1,1′-bis(4-hydroxyphenyl)cyclohexane, 2,2′-methylenebis(4-methyl-6-t-butylphenol), 2,2′-methylenebis(4-ethyl-6-t-butylphenol), 2,2′-methylenebis(6-(1-methylcyclohexyl)-4-methylphenol), 4,4′-butylidenebis(3-methyl-6-t-butylphenol), 3,9-bis(2-(3-t-butyl-4-hydroxy-5-methylphenylpropionyloxy)-1,1-dimethylethyl)-2,4,8,10-tetraoxaspiro(5,5)undecane, 4,4′-thiobis(3-methyl-6-t-butylphenol), 4,4′-bis(3,5-di-t-butyl-4-hydroxybenzyl) sulfide, 4,4′-thiobis(6-t-butyl-2-methylphenol), 2,5-di-t-butylhydroquinone, 2,5-di-t-amylhydroquinone, 2-t-butyl-6-(3-t-butyl-2-hydroxy-5-methylbenzyl)-4-methylphenyl acrylate, 2,4-dimethyl-6-(1-methylcyclohexyl styrenated phenol, and 2,4-bis((octylthio)methyl)-5-methylphenol.

Examples of the phosphorus-based antioxidant include bis(2,6-di-t-butyl-4-methylphenyl)pentaerythritol diphosphite, tris(2,4-di-t-butylphenylphosphite), tetrakis(2,4-di-t-butyl-5-methylphenyl)-4,4′-biphenylenediphosphonite, 3,5-di-t-butyl-4-hydroxybenzylphosphonate-diethyl ester, bis-(2,6-dicumylphenyl)pentaerythritol diphosphite, 2,2-methylenebis(4,6-di-t-butylphenyl)octylphosphite, tris(mixed mono- and di-nonylphenylphosphite), bis(2,4-di-t-butylphenyl)pentaerythritol diphosphite, bis(2,6-di-t-butyl-4-methoxycarbonylethyl-phenyl)pentaerythritol diphosphite, and bis(2,6-di-t-butyl-4-octadecyloxycarbonylethylphenyl)pentaerythritol diphosphite.

Examples of the thioether-based antioxidant include dilauryl-3,3′-thiodipropionate, bis(2-methyl-4-(3-n-dodecyl)thiopropionyloxy)-5-t-butylphenyl)sulfide, distearyl-3,3′-thiodipropionate, and pentaerythritol-tetrakis(3-lauryl)thiopropionate.

### (Filler)

The photosensitive resin composition according to the present embodiment may further include a filler. As the filler, an appropriate filler can be selected according to the mechanical properties and the thermal properties required for a resin film made of the photosensitive resin composition.

Specific examples of the filler include inorganic fillers and organic fillers.

Specific examples of the inorganic fillers include silica such as fused crushed silica, fused spherical silica, crystalline silica, secondary agglomerated silica, and superfine powder silica; metal compounds such as alumina, silicon nitride, aluminum nitride, boron nitride, titanium oxide, and silicon carbide, aluminum hydroxide, magnesium hydroxide, and titanium white; talc; clay; mica; and glass fiber. As the inorganic filler, one kind or a combination of two or more kinds of the specific examples can be used.

Specific examples of the organic fillers include organosilicone powder and polyethylene powder. As the organic fillers, one kind or a combination of two or more kinds of the specific examples can be used.

### (Preparation of Photosensitive Resin Composition)

A method for preparing the photosensitive resin composition in the present embodiment is not limited, and a known method can be used according to the components included in the photosensitive resin composition.

For example, it can be prepared by mixing and dissolving the components in a solvent.

### (Photosensitive Resin Composition and Cured Film)

The photosensitive resin composition according to the present embodiment is used as follows. The photosensitive resin composition is applied to a surface provided with a metal such as Al or Cu, then pre-baking to dry, thereby forming a resin film, and the resin film is patterned into a desired shape by exposure and development, and then cured by post-baking to form a cured film.

Furthermore, in a case of manufacturing a permanent film, a heat treatment under pre-baking conditions, such as a time equal to or longer than 30 seconds and equal to or shorter than 1 hour at a temperature equal to or higher than 50° C. and equal to or shorter than 150° C., can be performed. In addition, with regard to the conditions for post-baking, for example, the heat treatment can be performed at a temperature of 150° C. or higher and 250° C. or lower for 30 minutes or more and 10 hours or less.

The viscosity of the photosensitive resin composition according to the present embodiment can be appropriately set according to a desired thickness of the resin film. The viscosity of the photosensitive resin composition can be adjusted by adding a solvent. Furthermore, during the adjustment, it is necessary to keep the content of the urea compound and the acyclic amide compound in the solvent constant.

The upper limit value of the viscosity of the photosensitive resin composition according to the present embodiment may be, for example, 5,000 mPa·s or less, 4,000 mPa's or less, or 3,000 mPa·s or less. In addition, the lower limit value of the viscosity of the photosensitive resin composition according to the present embodiment may be, for example, 10 mPa·s or more, or 50 mPa·s or more, depending on a desired thickness of the resin film.

A film obtained from the photosensitive resin composition of the present embodiment has a maximum elongation of 10% to 200%, and preferably 20% to 150%, and an average elongation of 1% to 150%, and preferably 2% to 120%, as measured by a tensile test using a Tensilon tester.

The film obtained from the photosensitive resin composition of the present embodiment can have a tensile strength of 30 to 300 MPa, and preferably 50 to 200 MPa.

As described above, the photosensitive resin composition of the present embodiment can provide a cured product such as a film, having an excellent mechanical strength. A reason thereof is not clear, but is presumed to be due to the excellent properties of the rigid polyimide of the present invention.

The film made of the photosensitive resin composition of the present embodiment has an excellent low dielectric loss tangent, and has a dielectric loss tangent (tan δ) of 0.008 or less, preferably 0.007 or less, and more preferably 0.006 or less, as measured at a frequency of 10 GHz.

The curing shrinkage of the film made of the photosensitive resin composition of the present embodiment is suppressed, and the coefficient of linear thermal expansion (CTE) can be set to 200 ppm/° C. or less, and preferably 150 ppm/° C. or less.

In the present embodiment, it is preferable that the polyimide included in the polymer B includes no halogen atom. With this, a cured product such as a film, made of the photosensitive resin composition, is excellent in hydrolysis resistance, and deterioration of the mechanical properties and the like can be suppressed.

Specifically, since a cured product (film) made of a photosensitive resin composition including a polymer A and a polymer B including a polyimide including no halogen atom has excellent hydrolysis resistance, a decrease rate in elongation (maximum value) represented by the following expression is 20% or less, preferably 15% or less, and more preferably 12% or less even after performing a HAST test (unsaturated high pressure steam test) for 96 hours under the conditions of a temperature of 130° C. and a relative humidity of 85% RH.

[(Elongation before test−Elongation after test)/Elongation before test)]×100

### (Use)

The photosensitive resin composition (negative photosensitive resin composition) of the present embodiment is used for forming a resin film for a semiconductor device such as a permanent film and a resist. Among these, from the viewpoint of expressing the improvement of the adhesiveness between the photosensitive resin composition and an Al pad after pre-baking and the suppression of generation of residues of the photosensitive resin composition during development in a well-balanced manner, the viewpoint of improving the adhesiveness between a cured film of the photosensitive resin composition and a metal after postbaking, and in addition, the viewpoint of improving the chemical resistance of the photosensitive resin composition after post-baking, it is preferable that the photosensitive resin composition is used for forming a permanent film.

Furthermore, in the present embodiment, the resin film includes a cured film of the photosensitive resin composition. That is, the resin film according to the present embodiment is obtained by curing the photosensitive resin composition.

The permanent film is composed of a resin film obtained by pre-baking, exposing, and developing the photosensitive resin composition to perform patterning into a desired shape, and post-baking to perform curing. The permanent film can be used as a protective film, an interlayer film, a dam material, and the like for a semiconductor device.

The resist is, for example, composed of a resin film obtained by applying the photosensitive resin composition to an object to be masked in a resist by a method such as spin coating, roll coating, flow coating, dip coating, spray coating, and doctor coating, and removing the solvent from the photosensitive resin composition.

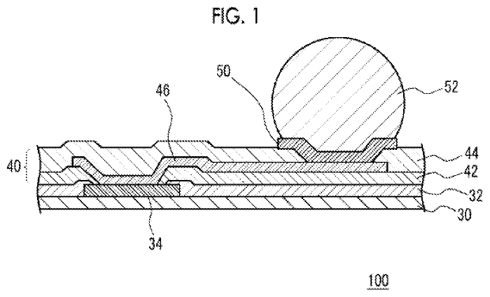

An example of the semiconductor device according to the present embodiment is shown in FIG. 1.

A semiconductor device 100 according to the present embodiment can be a semiconductor device provided with the resin film. Specifically, one or more of the group consisting of a passivation film 32, an insulating layer 42, and an insulating layer 44 in the semiconductor device 100 can be used for a resin film comprising the cured product of the present embodiment. Here, the resin film is preferably the above-mentioned permanent film.

The semiconductor device 100 is, for example, a semiconductor chip. In this case, for example, by mounting the semiconductor device 100 on a wiring substrate through a bump 52, it is possible to obtain a semiconductor package.

The semiconductor device 100 is provided with a semiconductor substrate having a semiconductor element such as a transistor provided thereon, and a multilayered wiring layer (not shown in the drawing) provided on the semiconductor substrate. An interlayer insulating film 30 and an uppermost layer wiring 34 provided over the interlayer insulating film 30 are provided on the uppermost layer of the multilayered wiring layer. The uppermost layer wiring 34 is composed of aluminum Al, for example. In addition, a passivation film 32 is provided over the interlayer insulating film 30 and the uppermost layer wiring 34. An opening through which the uppermost layer wiring 34 is exposed is provided in a part of the passivation film 32.

A rewiring layer 40 is provided on the passivation film 32. The rewiring layer 40 has an insulating layer 42 provided on the passivation film 32, a rewiring 46 provided on the insulating layer 42, and an insulating layer 44 provided on the insulating layer 42 and the rewiring 46. An opening connected to the uppermost layer wiring 34 is formed in the insulating layer 42. The rewiring 46 is formed on the insulating layer 42 and in the opening provided in the insulating layer 42, and connected to the uppermost layer wiring 34. An opening connected to the rewiring 46 is provided in the insulating layer 44.

A bump 52 is formed in the opening provided in the insulating layer 44, for example, through an Under Bump Metallurgy (UBM)) layer 50. The semiconductor device 100 is connected to a wiring substrate or the like, for example, through the bump 52.

Although the embodiments of the present invention have been described above, these are examples of the present invention and various configurations other than those can be adopted within the scope that does not impair the effects of the present invention.

### EXAMPLES

The present invention will be described in more detail below with reference to Examples, but the present invention is not limited thereto. Furthermore, in the present Examples, all parts and percentages are by weight, all temperatures are in degrees Celsius, and pressures are at or near atmospheric, unless otherwise indicated.

### Synthesis Example 1

### (Synthesis of Maleic Anhydride-Modified Norbornene Monomer (DMMIBuNB, 1-[4-(5-2-Norbornyl)butyl]-3,4-dimethyl-pyrrole-2,5-dione))

200 mL of toluene, and then DMMI potassium (35 g, 0.21 mol) and 18-crown-6 (5.7 g, 0.021 mol, 10% by mole) were charged into a 1 L four-neck round bottom flask (RBF) provided with a thermowell, a nitrogen inlet condenser, an addition funnel, and a mechanical stirrer, with stirring. Endo-exo-NBBuBr (45 g, 0.20 mol) in 200 ml of toluene was added to the addition funnel over 5 minutes. The mixture was heated to 100° C. and an off-white slurry was observed. The stirring of the mixture was further continued for 6.5 hours as the color changed from the initially observed off-white to dark green and then to reddish brown. The reaction was monitored by GC and found to be completed with 73.6% of a product and 15.6% of unreacted endo-exo-NBBuBr.

Then, the reaction mixture was cooled to room temperature, then quenched by addition of 250 mL of water, and then diluted with 150 ml of toluene. The aqueous layer was extracted with CH₂Cl₂(2×200 mL), and the organic layer was washed with brine, dried over Na₂SO₄, filtered, and evaporated to obtain 55 g of a crude product as a brown oil. The crude product was adsorbed on 55 g of SiO₂, chromatographed on 330 g of SiO₂, and eluted with pentane (3 L), 2% EtOAc in pentane (5 L), 3% EtOAc in heptane (3 L), and 4% EtOAc in heptane (2 L). From the concentrated purified fractions, 31 g of a product was obtained as a colorless viscous oil (a yield of 58%) with a purity of 99.3% by HPLC and 7.0 g of a product (a yield of 13.1%) was obtained as a separate fraction with a purity of 99.09% by HPLC. The combined yield for the reaction was 71%. ¹H-NMR and MS were consistent with the structure of DMMIBuNB. The reaction formula is shown below.

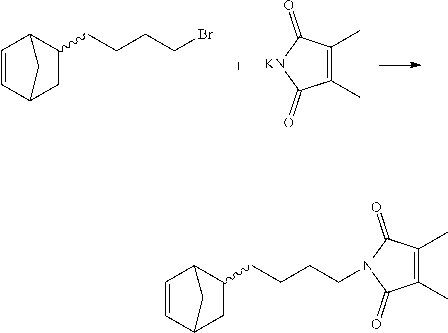

### (Synthesis of Polymer (DMMI-PNB (1)))

596 g of 1-[4-(5-2-norbornyl)butyl]-3,4-dimethyl-pyrrole-2,5-dione) obtained by the method, 1,849 g of toluene, and 457 g of ethyl acetate were charged into a nitrogen-substituted reaction vessel. Furthermore, 66 ml of a toluene solution of (toluene)bis(perfluorophenyl)nickel with a concentration of 10% by weight was added thereto and reacted at 49° C. for 2 hours. After 2 hours, 11 g of water was added to the mixture to stop the reaction, thereby obtaining a polymer solution. A conversion to polymers was 99%.

150 g of ethyl acetate, 463 g of isopropanol, 254 g of acetic acid, 481 g of a hydrogen peroxide solution (30%), and 601 g of water were added to 100 parts by weight of the prepared polymer solution, and the mixture was stirred at 160 rpm while heating to 50° C. After the temperature reached 50° C., the mixture was further stirred for 30 minutes. After 30 minutes, the stirring speed was lowered to 50 rpm, 154 g of isopropanol was added thereto, and the mixture was stirred for 10 minutes and allowed to stand at 50° C. for 30 minutes. After standing, the mixture was separated into an organic phase and an aqueous phase, and the aqueous phase was discarded. The obtained resin solution was reprecipitated with MeOH, filtered, and vacuum-dried at 50° C. to obtain 545 g of a polymer (DMMI-PNB (1)). Mw was 100,000.

### Synthesis Example 2

### (Synthesis of Maleic Anhydride-Modified Norbornene Monomer (DMMIBuNB, 1-[4-(5-2-Norbornyl)butyl]-3,4-dimethyl-pyrrole-2,5-dione))

Dimethylmaleic anhydride (42.6 g, 0.34 mol) was dissolved in toluene (300 mL) at room temperature in a 500 mL round bottom flask. The solution was placed under a nitrogen gas atmosphere to remove oxygen. The reaction flask was placed in an ice bath to prevent excessive heating resulting from the exothermic reaction. Once the dimethylmaleic anhydride was dissolved, a dropping funnel including 5-norbornene-2-butylamine (49.6 g, 0.30 mol) was installed and a norbornene compound was added dropwise to the reaction flask over 3 hours. The dropping funnel was removed, and a Dean-Stark tube and a reflux condenser were installed in the flask. The solution was heated to reflux in an oil bath set at 125° C. and the reaction was stirred at that temperature for 18 hours. About 6 mL of water was collected in the Dean-Stark tube during this time. The flask was removed from the oil bath and cooled to room temperature. The toluene solvent was removed using an evaporator to obtain a yellow oily substance. The crude product was applied to a flash chromatography column (250 g silica gel) and eluted with a solvent mixture of 1.7 liters of cyclohexane/ethyl acetate (95/5 wt ratio). The elution solvent was removed using an evaporator, and then the residue was dried under vacuum at 45° C. for 18 hours to obtain 80.4 g (92.7% yield) of a desired product. The reaction formula is shown below.

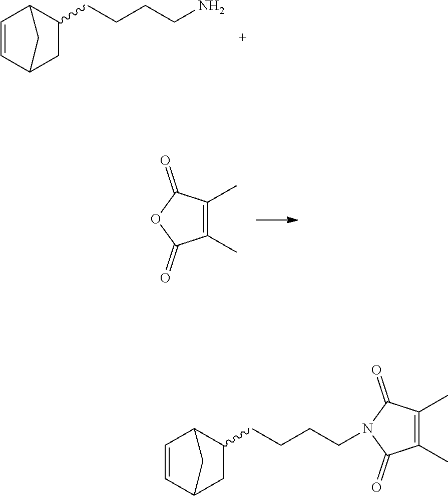

### (Synthesis of Polymer (DMMI-PNB (2)))

After bubbling nitrogen through an appropriately sized reaction vessel provided with a stirrer and a condenser for 1 hour, 1-[4-(5-2-norbornyl)butyl]-3,4-dimethyl-pyrrole-2,5-dione (NBBuDMMI) (24.60 g, 90 mmol) and triethylsilane (3.14 g, 27 mmol) were charged into the reaction vessel. Furthermore, cyclopentyl methyl ether (CPME) (16.04 g) and ethyl acetate (EA) (1.98 g) were added thereto to obtain a reaction solution. The reaction solution was heated to 70° C. with stirring under a nitrogen flow (50 mL/min). A solution prepared by dissolving a catalyst (palladium (II) (acetonitrile) bis(triisopropylphosphine)acetate tetrakis(2,3,4,5,6-pentafluorophenyl) borate, Pd-1206) (0.0434 g) and a cocatalyst (N,N-dimethylanilinium tetrakis(pentafluorophenyl)borate, DANFABA) (0.0288 g) in ethyl acetate (EA) (3.37 g) was added to the reaction solution to obtain NBBuDMMI:catalyst:cocatalyst=2,500:1:1 (molar ratio). Then, polymerization was performed at 70° C. for 3 hours, and after the polymerization, the reaction was stopped by standing to cool.

The obtained polymerization solution was diluted with tetrahydrofuran to manufacture a diluted solution, and then the diluted solution was added dropwise to a methanol solution to precipitate a white solid. The obtained white solid was collected and vacuum-dried at a temperature of 50° C. to obtain 20.02 g of a polymer (DMMI-PNB (2)). Mw was 6,000.

The following compounds were used in Synthesis Examples 3 to 6.
4,4′-(Hexafluoroisopropylidene)diphthalic anhydride (hereinafter also referred to as 6FDA) represented by the following formula

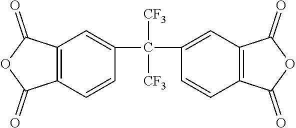 [SMILES: O=C1OC(=O)c2cc(C(c3ccc4c(c3)C(=O)OC4=O)(C(F)(F)F)C(F)(F)F)ccc21]

2,2′-Bis(trifluoromethyl)benzidine (hereinafter also referred to as TFMB) represented by the following formula

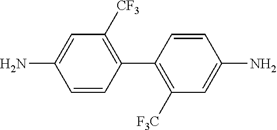 [SMILES: Nc1ccc(-c2ccc(N)cc2C(F)(F)F)c(C(F)(F)F)c1]

4-[4-(1,3-Dioxoisobenzofuran-5-ylcarbonyloxy)-2,3,5-trimethylphenyl]-2,3,6-trimethylphenyl-1,3-dioxoisobenzofuran-5-carboxylate (hereinafter also referred to as TMPBP-TME) represented by the following formula
4,4-Diamino-3,3-diethyl-5,5-dimethyldiphenylmethane (hereinafter also referred to as MED-J) represented by the following formula

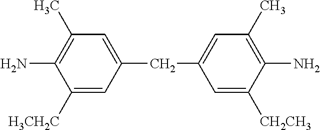

A mixture (hereinafter also referred to as TMDA) of 1-(4-aminophenyl)-1,3,3-trimethylphenylindan-6-amine and 1-(4-aminophenyl)-1,3,3-trimethylphenylindan-5-amine, represented by the following formula

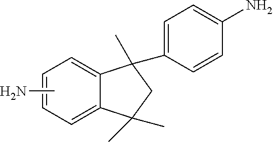

9,9-Bis(3-methyl-4-aminophenyl)fluorene (hereinafter also referred to as BTFL) represented by the following formula

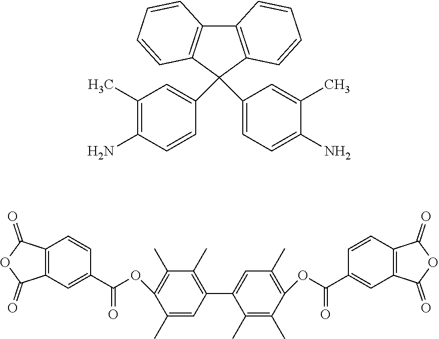 [SMILES: Cc1cc(C2(c3ccc(N)c(C)c3)c3ccccc3-c3ccccc32)ccc1N ; Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O]

### Synthesis Example 3

### (Synthesis of Polymer (DMMI-PI (1)))

First, 16.09 g (50.2 mmol) of TFMB, 11.05 g (24.9 mmol) of 6FDA, and 15.39 g (24.9 mmol) of TMPBP-TME were charged into an appropriately sized reaction vessel provided with a stirrer and a condenser. Thereafter, 99.24 g of γ-butyrolactone (hereinafter also referred to as GBL) was added to the reaction vessel.

After bubbling nitrogen through the reaction vessel for 10 minutes, the temperature was raised to 60° C. with stirring and the reaction was allowed to proceed for 1 hour. A solution was previously created by dissolving 0.38 g (3.0 mmol) of dimethylmaleic anhydride in 0.78 g of γ-butyrolactone, and this solution was charged into the reaction vessel and further reacted for 30 minutes. Furthermore, the solution was reacted at 175° C. for 3 hours to manufacture a polymerization solution in which a diamine and an acid anhydride were polymerized and the terminals were blocked.

The obtained polymerization solution was diluted with acetone to manufacture a diluted solution, and then the diluted solution was added dropwise to a methanol solution to precipitate a white solid. The obtained white solid was collected and vacuum-dried at a temperature of 120° C. to obtain 34.78 g of a polymer (DMMI-PI (1)) represented by the following formula.

GPC measurement of the polymer revealed a weight-average molecular weight Mw of 76,991, a polydispersity (weight-average molecular weight Mw/number-average molecular weight Mn) of 2.06, and a terminal blocking rate of 93%. In the formula, min=1:1.

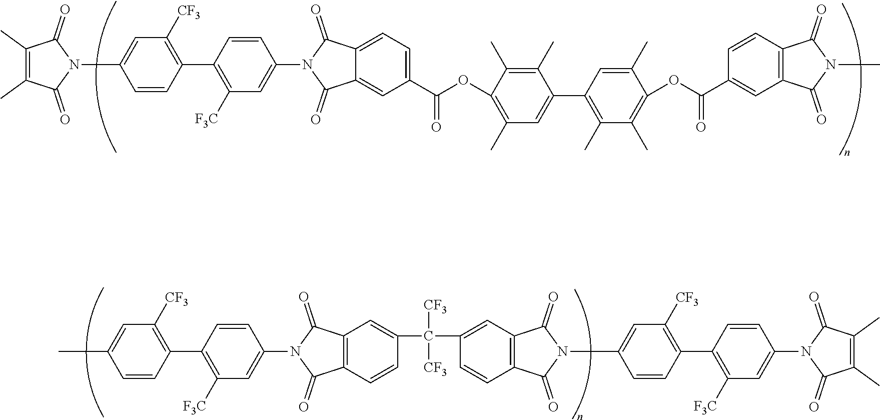

In a case where the polymer was subjected to IR measurement, peaks derived from amide groups around 1,480, 1,550, and 1,670 cm⁻¹ disappeared, confirming that imidization was completed.

### Synthesis Example 4

### (Synthesis of Polymer (DMMI-PI (2)))

First, 43.99 g (155.8 mmol) of MED-J and 89.22 g (144.2 mmol) of TMPBP-TME were charged into an appropriately sized reaction vessel provided with a stirrer and a condenser. Thereafter, 399.64 g of γ-butyrolactone (hereinafter also referred to as GBL) was added to the reaction vessel.

After bubbling nitrogen through the reaction vessel for 10 minutes, the temperature was raised to 60° C. with stirring and the reaction was allowed to proceed for 1 hour. A solution was previously created by dissolving 8.73 g (69.2 mmol) of dimethylmaleic anhydride in 26.19 g of gamma-butyrolactone, and this solution was charged into the reaction vessel and further reacted for 30 minutes. Furthermore, the solution was reacted at 175° C. for 3 hours to manufacture a polymerization solution in which a diamine and an acid anhydride were polymerized and the terminals were blocked.

The obtained polymerization solution was diluted with tetrahydrofuran to manufacture a diluted solution, and then the diluted solution was added dropwise to a methanol solution to precipitate a white solid. The obtained white solid was collected and vacuum-dried at a temperature of 80° C. to obtain 125.88 g of a polymer (DMMI-PI (2)) represented by the following formula.

GPC measurement of the polymer revealed a weight-average molecular weight Mw of 74,000, a polydispersity (weight-average molecular weight Mw/number-average molecular weight Mn) of 2.62, and a terminal blocking rate of 65%.

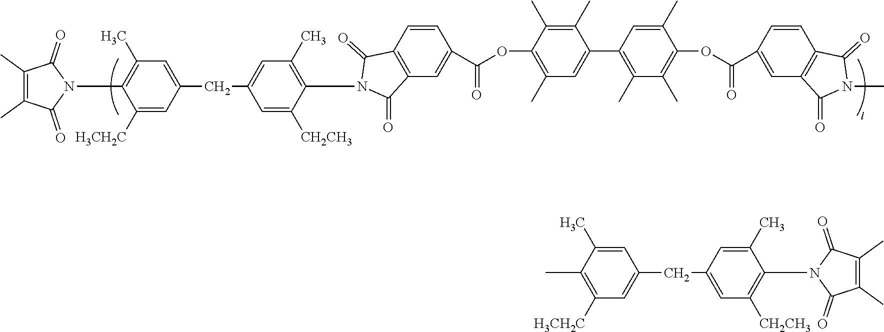

### Synthesis Example 5

### (Synthesis of Polymer (DMMI-PI (3)))

First, 7.17 g (25.4 mmol) MED-J, 6.76 g (25.4 mmol) TMDA, and 30.47 g (49.3 mmol) of TMPBP-TME were charged into an appropriately sized reaction vessel provided with a stirrer and a condenser. Thereafter, 159.82 g of γ-butyrolactone (hereinafter also referred to as GBL) was added to the reaction vessel.

After bubbling nitrogen through the reaction vessel for 10 minutes, the temperature was raised to 60° C. with stirring and the reaction was allowed to proceed for 1 hour. A solution was previously created by dissolving 1.12 g (8.9 mmol) of dimethylmaleic anhydride in 4.47 g of gamma-butyrolactone, and this solution was charged into the reaction vessel and further reacted for 30 minutes. Furthermore, the solution was reacted at 175° C. for 3 hours to manufacture a polymerization solution in which a diamine and an acid anhydride were polymerized and the terminals were blocked.

The obtained polymerization solution was diluted with tetrahydrofuran to manufacture a diluted solution, and then the diluted solution was added dropwise to a methanol solution to precipitate a white solid. The obtained white solid was collected and vacuum-dried at a temperature of 80° C. to obtain 40.62 g of a polymer (DMMI-PI (3)).

GPC measurement of the polymer revealed a weight-average molecular weight Mw of 77,000, a polydispersity (weight-average molecular weight Mw/number-average molecular weight Mn) of 2.07, and a terminal blocking rate of 98%.

### Synthesis Example 6

### (Synthesis of Polymer (DMMI-PI (4)))

First, 7.17 g (25.4 mmol) MED-J, 9.55 g (25.4 mmol) of BTFL, and 30.47 g (49.3 mmol) of TMPBP-TME were charged into an appropriately sized reaction vessel provided with a stirrer and a condenser. Thereafter, 169.88 g of γ-butyrolactone (hereinafter also referred to as GBL) was added to the reaction vessel.

After bubbling nitrogen through the reaction vessel for 10 minutes, the temperature was raised to 60° C. with stirring and the reaction was allowed to proceed for 1 hour. A solution was previously created by dissolving 1.12 g (8.9 mmol) of dimethylmaleic anhydride in 4.47 g of gamma-butyrolactone, and this solution was charged into the reaction vessel and further reacted for 30 minutes. Furthermore, the solution was reacted at 175° C. for 3 hours to manufacture a polymerization solution in which a diamine and an acid anhydride were polymerized and the terminals were blocked.

The obtained polymerization solution was diluted with tetrahydrofuran to manufacture a diluted solution, and then the diluted solution was added dropwise to a methanol solution to precipitate a white solid. The obtained white solid was collected and vacuum-dried at a temperature of 80° C. to obtain 43.69 g of a polymer (DMMI-PI (4).

GPC measurement of the polymer revealed a weight-average molecular weight Mw of 83,000, a polydispersity (weight-average molecular weight Mw/number-average molecular weight Mn) of 2.10, and a terminal blocking rate of 86%.

The following components were used in Examples below.
Photosensitive agent: 1-Chloro-4-propoxythioxanthone (SPEEDCURE CPTX (trade name) manufactured by Lambson, UK)
Solvent: Propylene glycol monomethyl ether acetate
Adhesion aid: 3-Trimethoxysilylpropyl succinic anhydride (trade name “X-12-967C” manufactured by Shin-Etsu Chemical Co., Ltd.)

### Examples 1 to 7 and Comparative Examples 1 and 2

The components shown in Table 1 were mixed to prepare a photosensitive resin composition.

The obtained photosensitive resin composition was spin-coated on a surface of a silicon wafer so that the film thickness after drying was 10 μm, pre-baked at 120° C. for 3 minutes, and then exposed to light at 2,000 mJ/cm² with a high-pressure mercury lamp. Thereafter, curing was performed for 120 minutes at 200° C. in a nitrogen atmosphere to prepare a film. Furthermore, in Example 5, a film was prepared in the same manner as in Example 1, except that pre-baking was performed at 150° C. for 3 minutes and the exposure amount was changed to 800 mJ/cm².

### (Tensile Strength, Elongation, and Modulus of Elasticity)

A tensile test (stretching speed: 5 mm/min) was performed in an atmosphere of 23° C. on a test piece (6.5 mm×60 mm×10 μm thick) cut out from the obtained film. The tensile test was performed using a tensile tester (Tensilon RTC-1210A) manufactured by Orientec Co., Ltd. A strength was obtained by measuring five test pieces and averaging the stress at the breaking point. A tensile elongation was calculated from the breaking distance and the initial distance, and a maximum value of the elongation was obtained. A tensile modulus of elasticity was calculated from the initial slope of the obtained stress-strain curve, and the average was taken as the modulus of elasticity. The results are shown in Table 1.

Furthermore, the test piece cut out from the obtained film was subjected to HAST (unsaturated high pressure steam test) for 96 hours under the conditions of a temperature of 130° C. and a relative humidity of 85% RH, and then a maximum value of the elongation was determined as described above. The results are shown in Table 1.

### (Coefficient of Linear Thermal Expansion (CTE))

A strip-shaped test piece having a length of 13 mm and a width of 4 mm was cut from the obtained film. A thermomechanical measurement in a tensile mode was performed at a chuck-to-chuck distance of 10 mm and an average linear thermal expansion coefficient (CTE, 50° C. to 100° C., or 100° C. to 200° C.) was determined from a thermal expansion curve. The results are shown in Table 1.

### (Glass Transition Temperature: Tg)

A strip-shaped test piece having a length of 50 mm and a width of 10 mm was cut from the obtained film. The test piece was subjected to dynamic viscoelasticity measurement at a chuck-to-chuck distance of 20 mm and the obtained peak temperature of the loss tangent (tan δ) was taken as a glass transition temperature (Tg). The measurement conditions were a nitrogen stream of 30 ml/min, an applied frequency of 1 Hz, and a heating rate of 5° C./min. The results are shown in Table 1.

### (Dielectric Loss Tangent Df)

The photosensitive resin compositions of Examples 1 to 7 and Comparative Examples 1 and 2 were applied on a substrate, and the coating films were dried at 120° C. for 10 minutes, subjected to PLA exposure (540 mJ), and cured at 200° C. for 2 hours in a nitrogen atmosphere to obtain films having a film thickness of 100 μm. The dielectric loss tangents at 10 GHz of the obtained films were measured by a cavity resonator method. The results are shown in Table 1.

TABLE 1

| | | | | | | | | | Compar- | Compar- |
|---|---|---|---|---|---|---|---|---|---|---|
| | | | | | | | | | ative | ative |
| | | Exam- | Exam- | Exam- | Exam- | Exam- | Exam- | Exam- | Exam- | Exam- |
| | Unit | ple 1 | ple 2 | ple 3 | ple 4 | ple 5 | ple 6 | ple 7 | ple 1 | ple 2 |
| DMMI-PNB (1) | Parts | 8.0 | 10.0 | 12.0 | 14.0 | | | | 20.0 | |
| | by mass | | | | | | | | | |
| DMMI-PNB (2) | Parts | | | | | 11.0 | 11.0 | 11.0 | | |
| | by mass | | | | | | | | | |
| DMMI-PI (1) | Parts | 12.0 | 10.0 | 8.0 | 6.0 | | | | | 20.0 |
| | by mass | | | | | | | | | |
| DMMI-PI (2) | Parts | | | | | 9.0 | | 4.5 | | |
| | by mass | | | | | | | | | |
| DMMI-PI (3) | Parts | | | | | | 9.0 | | | |
| | by mass | | | | | | | | | |
| DMMI-PI (4) | Parts | | | | | | | 4.5 | | |
| | by mass | | | | | | | | | |
| Photosensitive agent | Parts | 0.2 | 0.2 | 0.8 | 0.8 | 1.0 | 1.0 | 1.0 | 0.8 | 0.2 |
| | by mass | | | | | | | | | |
| Solvent | Parts | 79.8 | 79.8 | 79.8 | 79.8 | 79.0 | 79.0 | 79.0 | 79.8 | 79.8 |
| | by mass | | | | | | | | | |
| Total | Parts | 100.0 | 100.0 | 100.6 | 100.6 | 100.0 | 100.0 | 100.0 | 100.6 | 100.0 |
| | by mass | | | | | | | | | |
| Elongation (Max) before HAST | % | 68.2 | 57.7 | 55.8 | 41.4 | 46.0 | 51.3 | 46.9 | 21.0 | (*1) |
| Elongation (Max) after HAST | % | | | | | 40.0 | 47.4 | 39.4 | | (*1) |
| Modulus of elasticity (Max) | GPa | 2.8 | 2.7 | 2.9 | 2.6 | 2.3 | 3.0 | 2.7 | 1.3 | (*1) |
| Tensile strength (Max) | MPa | 142 | 121 | 127 | 103 | 105.6 | 88.2 | 110.5 | 40 | (*1) |
| CTE (50° C. to 100° C.) | ppm/ | 58 | 61 | 66 | 72 | 66 | 66 | 64 | 121 | (*1) |
| | ° C. | | | | | | | | | |
| CTE (100° C. to 200° C.) | ppm/ | 67 | 73 | 75 | 84 | 63 | 73 | 67 | 168 | (*1) |
| | ° C. | | | | | | | | | |
| Tg | ° C. | 236 | 218 | 223 | 207 | 241.1 | 244.3 | 263.3 | >300 | (*1) |
| Dielectric loss tangent | | 0.0040 | 0.0037 | 0.0038 | 0.0035 | 0.0045 | 0.0041 | 0.0048 | 0.0026 | 0.01 |
| Df (10 GHz) | | | | | | | | | | |

(*1) Not measured due to high dielectric loss tangent

From the results in Table 1, it was found that by allowing the photosensitive resin composition of the present invention to include a combination of a predetermined cyclic olefin resin and a polyimide, a resin film having an excellent low dielectric loss tangent and excellent mechanical properties can be obtained. Furthermore, it is presumed that the resin film also has excellent hydrolysis resistance, and suppression of deterioration of mechanical properties and the like.

In addition, in a case where the photosensitive resin compositions of Examples 1 to 7 were subjected to a photosensitivity test, it was confirmed that holes with a diameter of 20 μm could be formed in any of the photosensitive resin compositions.

This application claims priority based on Japanese Patent Application No. 2021-021545 filed on Feb. 15, 2021 and Japanese Patent Application No. 2021-105687 filed on Jun. 25, 2021, the entire disclosure of which is herein incorporated by reference.

### REFERENCE SIGNS LIST

30 interlayer insulating film
32 passivation film
34 uppermost layer wiring
40 rewiring layer
42 insulating layer
44 insulating layer
46 rewiring
50 UBM layer
52 bump
100 semiconductor device

What is claim is:

1. A photosensitive resin composition comprising:
a polymer A having a structural unit represented by General Formula (a); and
a polymer B including a polyimide having a group b represented by General Formula (b), 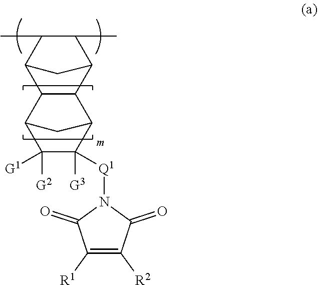
wherein, in General Formula (a), R¹ and R² each independently represent a hydrogen atom or an alkyl group having 1 to 3 carbon atoms, Q¹ represents a single bond or a divalent organic group, G¹, G², and G³ each independently represent a hydrogen atom or a substituted or unsubstituted hydrocarbon group having 1 to 30 carbon atoms, and m is 0, 1, or 2, 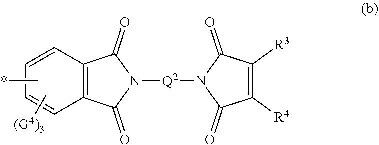
wherein, in General Formula (b), R³ and R⁴ each independently represent a hydrogen atom or an alkyl group having 1 to 3 carbon atoms, Q² represents a divalent organic group, G⁴'s each independently represent a hydrogen atom or a substituted or unsubstituted hydrocarbon group having 1 to 30 carbon atoms, and * represents a bonding hand.

2. The photosensitive resin composition according to claim 1,
wherein the divalent organic group of Q¹ is an alkylene group having 1 to 8 carbon atoms or a (poly)alkylene glycol chain.

3. The photosensitive resin composition according to claim 1,
wherein the polymer B includes a polyimide provided with the groups b represented by General Formula (b) at both terminals.

4. The photosensitive resin composition according to claim 1,
wherein the divalent organic group of Q² in General Formula (b) is represented by General Formula (b1), 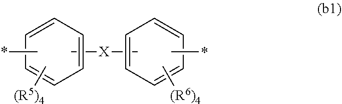
wherein, in General Formula (b1), R⁵ and R⁶ each independently represent a hydrogen atom, a haloalkyl group having 1 to 4 carbon atoms, an alkyl group having 1 to 3 carbon atoms, an alkoxy group having 1 to 3 carbon atoms, or a hydroxyl group, X represents a single bond, an alkylene group having 1 to 4 carbon atoms, a haloalkylene group having 1 to 4 carbon atoms, a divalent ether group derived from bisphenol A, a divalent ether group derived from bisphenol F, a divalent ether group derived from bisphenol S, or a divalent ether group derived from hexafluorobisphenol A, and * represents a bonding hand.

5. The photosensitive resin composition according to claim 1,
wherein the polymer (B) includes a polyimide provided with a group c represented by General Formula (c) at at least one terminal, and
wherein, in the polyimide included in the polymer (B), a ratio (b/b+c) of the number of moles of the group b to the total number of moles of the group b and the group c is 0.5 or more, 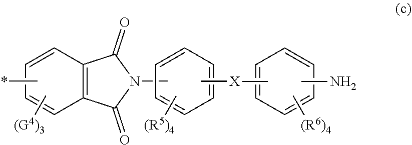
wherein, in General Formula (c), R⁵ and R⁶ each independently represent a hydrogen atom, a haloalkyl group having 1 to 4 carbon atoms, an alkyl group having 1 to 3 carbon atoms, an alkoxy group having 1 to 3 carbon atoms, or a hydroxyl group, X represents a single bond, an alkylene group having 1 to 4 carbon atoms, a haloalkylene group having 1 to 4 carbon atoms, a divalent ether group derived from bisphenol A, a divalent ether group derived from bisphenol F, a divalent ether group derived from bisphenol S, or a divalent ether group derived from hexafluorobisphenol A, G⁴'s each independently represent a hydrogen atom or a substituted or unsubstituted hydrocarbon group having 1 to 30 carbon atoms, and * represents a bonding hand.

6. The photosensitive resin composition according to claim 1,
wherein the polymer B includes a polyimide represented by General Formula (d), 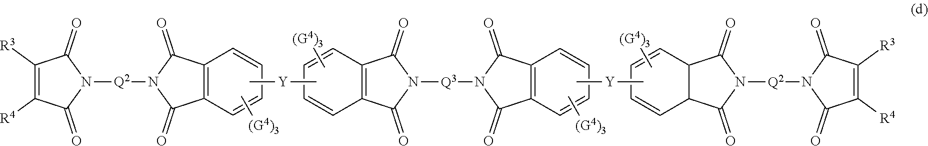
wherein, in General Formula (d), R³, R⁴, Q², and G⁴ each have the same definitions as in General Formula (b), and a plurality of R³'s, a plurality of R⁴'s, a plurality of Q²'s, and a plurality of G⁴'s may each be the same as or different from each other,
Y is selected from groups represented by General Formula (d1), General Formula (d2), and General Formula (d3), and a haloalkylene group having 1 to 5 carbon atoms, and a plurality of Y's may be the same as or different from each other, 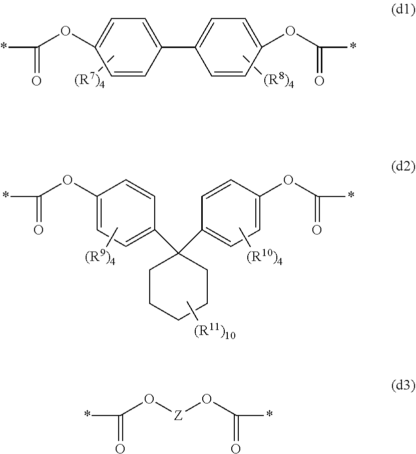
wherein, in General Formula (d1), R⁷ and R⁸ each independently represent a hydrogen atom, an alkyl group having 1 to 3 carbon atoms, or an alkoxy group having 1 to 3 carbon atoms, a plurality of R⁷'s and a plurality of R⁸'s may each be the same as or different from each other, and * represents a bonding hand,
wherein, in General Formula (d2), R⁹ and R¹⁰ each independently represent a hydrogen atom, an alkyl group having 1 to 3 carbon atoms, or an alkoxy group having 1 to 3 carbon atoms, a plurality of R⁹'s and a plurality of R¹⁰'s may each be the same as or different from each other, R¹¹ represents a hydrogen atom, an alkyl group having 1 to 3 carbon atoms, or an alkoxy group having 1 to 3 carbon atoms, a plurality of R¹¹'s may be the same as or different from each other, and * represents a bonding hand, and
wherein, in General Formula (d3), Z represents an alkylene group having 1 to 5 carbon atoms or a divalent aromatic group, and * represents a bonding hand, and
Q³ represents a repeating unit represented by General Formula (d4), 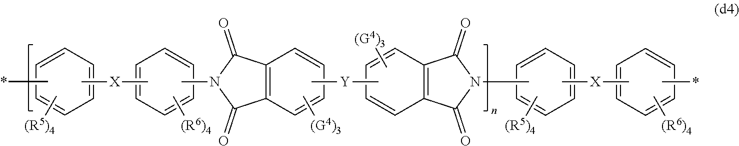
wherein, in General Formula (d4), R⁵, R⁶, and X each have the same definitions as in General Formula (b1), G⁴ has the same definition as in General Formula (b), Y has the same definition as in General Formula (d), n represents an integer of 20 to 200, and * represents a bonding hand.

7. The photosensitive resin composition according to claim 1, further comprising a photosensitizer.

8. The photosensitive resin composition according to claim 1, further comprising a silane coupling agent.

9. A cured film comprising a cured product of the photosensitive resin composition according to claim 1.

10. A semiconductor device including a resin film comprising a cured product of the photosensitive resin composition according to claim 1.

11. The semiconductor device according to claim 10, comprising:
an interlayer insulating film;
a resin film comprising a cured product of the photosensitive resin composition according to claim 1, provided over the interlayer insulating film; and
a rewiring embedded in the resin film.
